(19) United States
(12) Patent Application Publication
(10) Pub. No.: US 2026/0150604 A1
(43) Pub. Date: May 28, 2026

(54) SUBSTRATE PROCESSING METHOD AND SUBSTRATE PROCESSING DEVICE

(71) Applicant: Tokyo Electron Limited, Minato-ku, Tokyo (JP)

(72) Inventor: Koji KAGAWA, Koshi City, Kumamoto (JP)

(21) Appl. No.: 19/105,156

(22) PCT Filed: Aug. 15, 2023
(86) PCT No.: PCT/JP2023/029512

§ 371 Date: Feb. 20, 2025

(30) Foreign Application Priority Data
Aug. 29, 2022 (JP) 2022135695

(51) Int. Cl. H10P 50/68; H10P 72/00

(52) U.S. Cl. CPC H10P 50/683; H10P 72/0422

(57) ABSTRACT

This substrate processing method includes: preparing a substrate having a surface from which a titanium nitride film and a zirconium oxide film are exposed; and selectively etching the zirconium oxide film from among the titanium nitride film and the zirconium oxide film by supplying an etching solution containing hydrogen fluoride and an organic solvent, to the surface of the substrate.

### TECHNICAL FIELD

The present disclosure relates to a substrate processing method and a substrate processing apparatus.

### BACKGROUND

A substrate processing method described in Patent Document 1 includes etching zirconium oxide by using a processing solution containing sulfuric acid. The zirconium oxide is a material for a gate insulating film and is a high-dielectric constant material. The processing solution containing sulfuric acid is pre-heated to a temperature range of 150 to 180 degrees C.

A substrate processing method described in Patent Document 2 includes selectively etching a lower layer from among the lower layer and an upper layer by using a mixed solution of diluted hydrofluoric acid (DHF), where hydrofluoric acid is diluted with water, and isopropyl alcohol (IPA). The lower layer is glass containing boron or phosphorus. The upper layer is a silicon oxide film.

### PRIOR ART DOCUMENTS

### Patent Documents

Patent Document 1: Japanese Laid-Open Publication No. 2003-273066
Patent Document 2: Japanese Laid-Open Publication No. 2020-140984

One embodiment of the present disclosure provides a technique to selectively etch a zirconium oxide film from among a titanium nitride film and the zirconium oxide film.

### SUMMARY

According to one embodiment of the present disclosure, a substrate processing method includes: preparing a substrate including a surface on which a titanium nitride film and a zirconium oxide film are exposed; and selectively etching the zirconium oxide film from among the titanium nitride film and the zirconium oxide film by supplying an etching solution, which contains hydrogen fluoride and an organic solvent, to the surface of the substrate.

According to one embodiment of the present disclosure, it is possible to selectively etch a zirconium oxide film from among a titanium nitride film and a zirconium oxide film.

### BRIEF DESCRIPTION OF DRAWINGS

FIG. 1 is a cross-sectional view illustrating a substrate processing apparatus according to one embodiment.

FIG. 2 is a cross-sectional view illustrating an example of a substrate that is prepared.

FIG. 3 is a flowchart illustrating a substrate processing method according to one embodiment.

FIG. 4 is a diagram illustrating an example of a relationship between a composition ratio of an etching solution and an etching rate of a zirconium oxide film.

FIG. 5 is a diagram illustrating an example of a relationship between film types (TiN, TiSiN, SiN) and etching rates of films.

### DETAILED DESCRIPTION

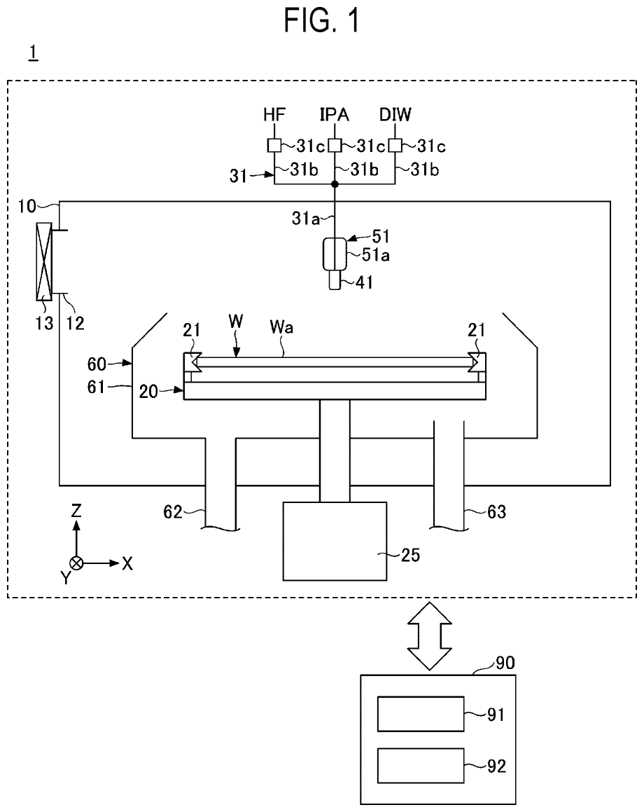

Hereinafter, embodiments of the present disclosure are described with reference to the accompanying drawings. In addition, in each drawing, the same reference numerals are given to the same or corresponding components, and descriptions thereof may be omitted. In FIG. 1, an X-axis direction, a Y-axis direction, and a Z-axis direction are directions perpendicular to one another. The X-axis direction and the Y-axis direction are a horizontal direction, and the Z-axis direction is a vertical direction.

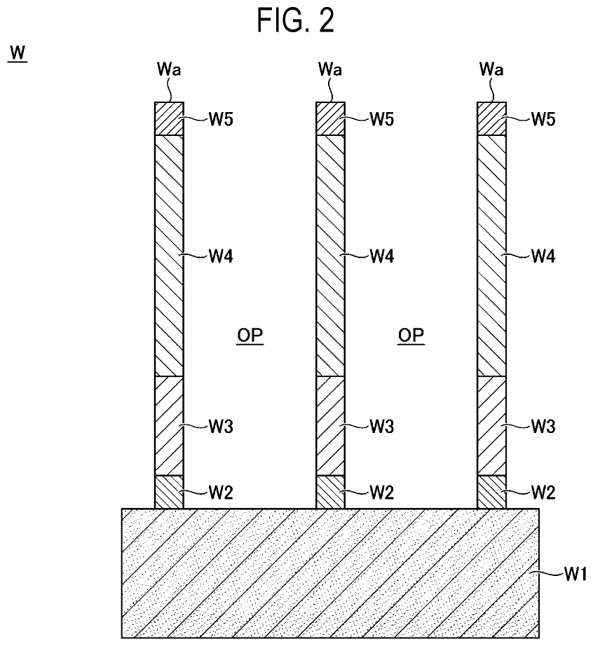

A substrate processing apparatus 1 according to one embodiment is described with reference to FIGS. 1 and 2. The substrate processing apparatus 1 processes a surface Wa of a substrate W by supplying a processing solution to the surface Wa of the substrate W. In the present embodiment, the substrate processing apparatus 1 is a single wafer type that processes substrates W one by one, but may be a batch type that processes a plurality of substrates W at once.

The single wafer type substrate processing apparatus 1 rotates the substrate W while holding the substrate W horizontally with the surface Wa of the substrate W facing upward, and supplies the processing solution to the surface Wa of the substrate W. The single wafer type substrate processing apparatus 1 includes, for example, a processing container 10, a substrate holder 20, a substrate rotator 25, a supplier 31, a nozzle 41, a mover 51, a collector 60, and a controller 90.

The processing container 10 accommodates components such as the substrate holder 20. A gate 12 and a gate valve 13 for opening or closing the gate 12 are provided at a sidewall of the processing container 10. The substrate W is loaded into the processing container 10 through the gate 12 by a transfer apparatus (not illustrated). Subsequently, the substrate W is processed inside the processing container by using the processing solution. Thereafter, the substrate W is unloaded out of the processing container 10 through the gate 12 by the transfer apparatus.

The substrate holder 20 is disposed inside the processing container 10 and holds the substrate W horizontally. The substrate holder 20 includes, for example, a claw 21 that holds an outer periphery of the substrate W. The claw 21 is provided in plurality at equal intervals in a circumferential direction of the substrate W. In addition, although not illustrated, the substrate holder 20 may hold a lower surface of the substrate W via vacuum suction.

The substrate rotator 25 rotates the substrate holder 20, thereby rotating the substrate W along with the substrate holder 20. The substrate holder 20 holds the substrate W such that a rotation centerline of the substrate W is aligned with a center of the surface Wa of the substrate W.

The supplier 31 supplies the processing solution to the surface Wa of the substrate W through the nozzle 41. The supplier 31 includes, for example, a common line 31a connected to the nozzle 41, a plurality of individual lines 31b branching from the common line 31a, and a device 31c provided for each individual line 31b. The device 31c includes, for example, an on-off valve, a flow-rate meter, and a flow-rate controller. The nozzle 41 sequentially discharges multiple types of processing solutions. However, the nozzle 41 may be provided for each type of the processing solutions, and the number of nozzles 41 may be plural.

The processing solutions include, for example, hydrogen fluoride (HF), isopropyl alcohol (IPA), and deionized water (DIW). HF is supplied in the form of an aqueous solution. The HF aqueous solution is generally called hydrofluoric acid. A HF concentration in the HF aqueous solution is, for example, 40% by mass to 65% by mass. The nozzle 41 may discharge a mixed solution of multiple types of the processing solutions such as a mixed solution of the HF aqueous solution and IPA. The supplier 31 may include a mixer (not illustrated) to mix the HF aqueous solution and IPA.

The mover 51 moves the nozzle 41 in both the horizontal and vertical directions. The mover 51 includes, for example, an arm 51a and a pivoting mechanism (not illustrated). The pivoting mechanism moves the nozzle 41 in the horizontal direction by pivoting the arm 51a. Further, the pivoting mechanism moves the nozzle 41 in the vertical direction by raising or lowering the arm 51a. In addition, the mover 51 may include a guide rail and a linear motion mechanism, instead of the arm 51a and the pivoting mechanism. The linear motion mechanism moves the nozzle 41 along the guide rail in both the horizontal and vertical directions.

The collector 60 collects the processing solution supplied to the substrate W. The collector 60 includes, for example, a cup 61. The cup 61 surrounds the outer periphery of the substrate W held by the substrate holder 20 and receives the processing solution splattered from the outer periphery of the substrate W. In the present embodiment, the cup 61 does not rotate together with the substrate holder 20, but may rotate together with the substrate holder 20. A bottom of the cup 61 is provided with a drain pipe 62 and an exhaust pipe 63. The drain pipe 62 discharges a liquid accumulated inside the cup 61. The exhaust pipe 63 discharges a gas accumulated inside the cup 61.

The controller 90 is, for example, a computer and includes a computation unit 91 such as a central processing unit (CPU) and a storage 92 such as a memory. The storage 92 stores programs for controlling various types of processing executed in the substrate processing apparatus 1. The controller 90 causes the computation unit 91 to execute the programs stored in the storage 92, thereby controlling the operation of the substrate processing apparatus 1.

The substrate processing apparatus 1 may also be a batch type apparatus to process the plurality of substrates W at once as described above. Although not illustrated, the batch type substrate processing apparatus 1 holds the plurality of substrates W vertically and processes the substrates W at once by immersing the substrates W in a processing solution stored in a processing tank. The batch type substrate processing apparatus 1 includes a substrate holder that holds the plurality of substrates W and a supplier that supplies the processing solution to the substrates W by supplying the processing solution into the processing tank.

Next, an example of the substrate W prepared is described with reference to FIG. 2. The substrate W includes, for example, a base substrate W1 such as a silicon wafer, a titanium nitride film W2, a conductive film W3, a silicon nitride film W4, and a zirconium oxide film W5, which are stacked in this order. The stacked structure of the substrate W is not limited to that illustrated in FIG. 2. For example, the substrate W may include a functional layer (not illustrated) between the base substrate W1 and the titanium nitride film W2.

The titanium nitride film W2, the conductive film W3, the silicon nitride film W4, and the zirconium oxide film W5 are stacked in this order on the base substrate W1. An opening OP is formed to penetrate the zirconium oxide film W5, the silicon nitride film W4, the conductive film W3, and the titanium nitride film W2. The opening OP is formed by dry etching, for example, using the zirconium oxide film W5 as a hard mask. The opening OP is, for example, a trench.

The substrate W is not particularly limited in the application thereof but is, for example, a semiconductor memory such as a DRAM. In this case, the titanium nitride film W2 is a bit line contact, and the conductive film W3 is a bit line. The titanium nitride film W2 may or may not contain silicon (Si). The conductive film W3 includes, for example, a Ru film, a W film, or a Mo film, and particularly, may include a Ru film. The conductive film W3 may be composed of a plurality of films, and for example, may include a TiSiN film and a Ru film stacked in this order on the titanium nitride film W2. The silicon nitride film W4 is a protective film that protects the conductive film W3.

After formation of the opening OP, the substrate processing apparatus 1 removes the zirconium oxide film W5 that has become unnecessary. The substrate processing apparatus 1 supplies an etching solution to the surface Wa of the substrate W, thus selectively etching the zirconium oxide film W5 from among the films W2 to W5 exposed on the surface Wa of the substrate W. This allows for the removal of the zirconium oxide film W5 while suppressing pattern collapse.

Typically, sulfuric acid is used as the etching solution for the zirconium oxide film W5, as described in Patent Document 1. However, sulfuric acid also etches the titanium nitride film W2. Therefore, the use of sulfuric acid causes a problem in that an uneven pattern on the substrate surface Wa collapses. Further, it is conceivable to use diluted hydrofluoric acid (DHF) where hydrofluoric acid (HF aqueous solution, HF concentration 40% by mass to 65% by mass) is diluted with water, but DHF has a problem in that it completely removes the silicon nitride film W4 before completely removing the zirconium oxide film W5.

Therefore, in the present embodiment, hydrofluoric acid (HF aqueous solution, HF concentration 40% by mass to 65% by mass) diluted with an organic solvent is used as the etching solution. The etching solution contains, for example, 0.7% by mass to 6.5% by mass of hydrogen fluoride (HF), 87.0% by mass to 98.6% by mass of the organic solvent, and 0.7% by mass to 6.5% by mass of water. In addition, it is desirable to minimize the content of water in the etching solution. If it is possible to prepare pure HF instead of the HF aqueous solution, it is desirable for the etching solution to contain 0.0% by mass of water.

Unlike Patent Document 1, by using hydrofluoric acid instead of sulfuric acid, the etching of the titanium nitride film W2 may be prevented, thereby suppressing the collapse of an uneven pattern. Further, unlike Patent Document 2, by diluting hydrofluoric acid with an organic solvent instead of diluting it with water, the etching of the silicon nitride film W4 may be prevented.

The equilibrium state of HF in the HF aqueous solution is as follows:

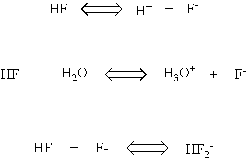

HF₂⁻ is an etching factor for both the silicon nitride film W4 and the zirconium oxide film W5. Non-dissociated HF is an etching factor for the zirconium oxide film W5. Therefore, by increasing an amount of non-dissociated HF in the processing solution, an etching selectivity ratio of the zirconium oxide film W5 to the silicon nitride film W4 (etching rate of W5/etching rate of W4) may be increased. To increase the amount of non-dissociated HF, a HF concentration in the etching solution may be increased, but this method has limitations in that an etching amount of SiN also increases accordingly.

Solvation occurs in solvents with a high dielectric constant (large polarization) such as DIW, and HF may take an ionic state such as F⁻ or HF₂⁻. In contrast, solvation is less likely to occur in solvents with a low dielectric constant (small polarization) such as organic solvents, and HF takes a non-dissociated state. In the present embodiment, by utilizing this phenomenon to dilute hydrofluoric acid with an organic solvent, the amount of non-dissociated HF increases, which enhances the etching selectivity ratio of the zirconium oxide film W5 to the silicon nitride film W4 (etching rate of W5/etching rate of W4).

The organic solvent constituting the etching solution is not particularly limited as long as it is compatible with water and has a lower relative dielectric constant than water, but may contain, for example, IPA, ethylene glycol (EG), acetic acid, ethanol, or methanol. The relative dielectric constant of the organic solvent may be equal to or less than half that of the relative dielectric constant of DIW. The relative dielectric constant of IPA is about one quarter of that of DIW.

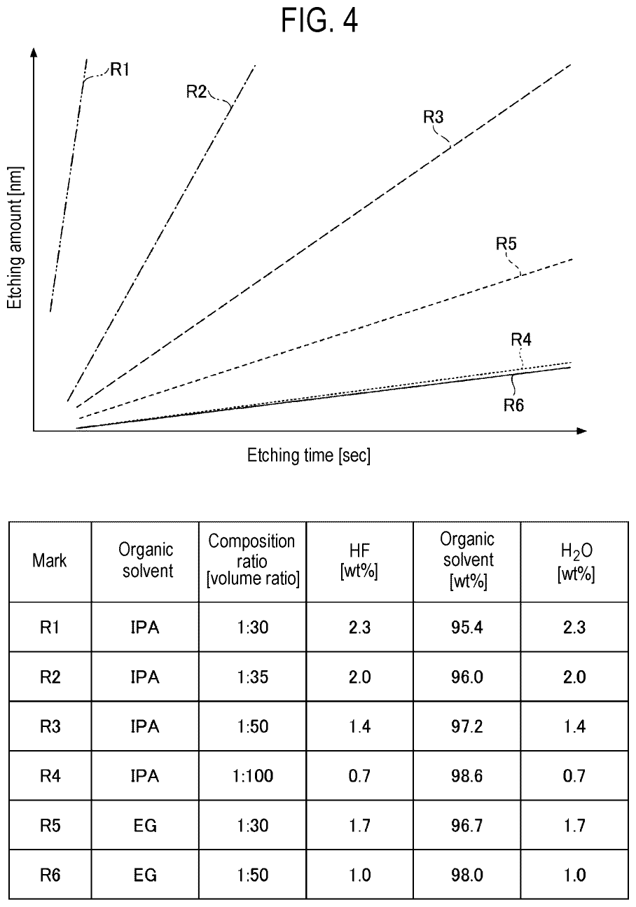

Next, an example of a relationship between a composition ratio of the etching solution and the etching rate of the zirconium oxide film W5 is described with reference to FIG. 4. In FIG. 4, the composition ratio indicates a volume ratio (HF aqueous solution:organic solvent) between the HF aqueous solution with a HF concentration of 50 wt % and the organic solvent. In FIG. 4, the greater the slope of the line, the greater the etching rate of the zirconium oxide film W5. From R1 to R4 illustrated in FIG. 4 or from R5 and R6 illustrated in FIG. 4, it is seen that the greater the HF content, the faster the etching rate of the zirconium oxide film W5. Further, from R3 and R6 illustrated in FIG. 4, it is seen that, when the volume ratio between the HF aqueous solution and the organic solvent is the same, IPA results in a faster etching rate than EG as the organic solvent.

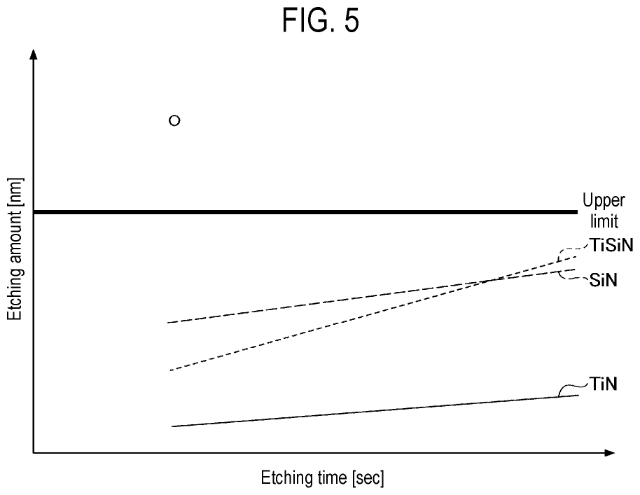

Next, an example of a relationship between film types (TIN, TiSiN, SiN) and etching rates of films is described with reference to FIG. 5. In FIG. 5, R1 illustrated in FIG. 4 is used as the etching solution. In FIG. 5, the “upper limit” represents a maximum etching amount at which no collapse of an uneven pattern occurs. In FIG. 5, the white circle indicates the etching amount of SiN when diluted hydrofluoric acid (DHF) is used as the etching solution. From FIG. 5, it is seen that the collapse of an uneven pattern may be suppressed by using an etching solution where a HF aqueous solution is diluted with an organic solvent.

As described above, the etching solution contains an organic solvent. Therefore, to enhance the etching rate of the zirconium oxide film W5, it is desirable for the film to contain an organic matter. The organic matter is derived, for example, from an organic zirconium compound. The zirconium oxide film W5 may be formed by dissolving the organic zirconium compound in an organic solvent and applying, drying, and then firing the resulting solution.

When supplying the etching solution, a temperature of the substrate W is, for example, equal to or less than 50 degrees C., and particularly, may be equal to or less than 30 degrees C. When using an etching solution where hydrofluoric acid is diluted with an organic solvent, unlike when sulfuric acid is used, heating of the substrate W is not required. In addition, when supplying the etching solution, it is sufficient as long as the temperature of the substrate W is room temperature or higher. For example, the temperature of the substrate W is equal to or greater than 5 degrees C., and particularly, may be equal to or greater than 20 degrees C.

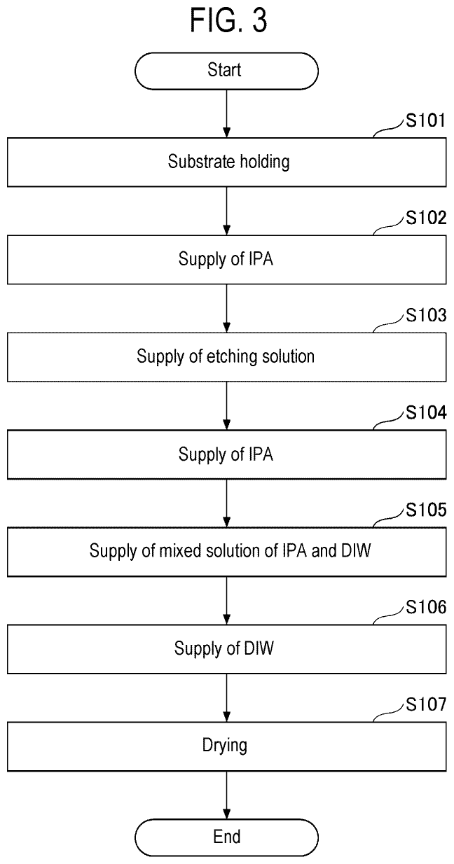

Next, a substrate processing method according to one embodiment is described with reference to FIG. 3. The substrate processing method includes, for example, steps S101 to S107, as illustrated in FIG. 3. Steps S101 to S107 are performed under control of the controller 90. The processing after step S101 is started when the transfer device (not illustrated) loads the substrate W into the processing container 10.

In addition, the substrate processing method does not need to include all of steps S101 to S107, but needs to include at least steps S101 and S103. Hereinafter, a case where IPA is used as the organic solvent constituting the etching solution in step S103 is described. In steps S102, S103 and S104, it is desirable to use the same organic solvent, but different organic solvents may also be used.

First, the substrate holder 20 holds the substrate W horizontally with the surface Wa of the substrate W facing upward (step S101). The substrate holder 20 holds the substrate W such that the rotation centerline of the substrate W passes through the center of the surface Wa of the substrate W. Thereafter, the substrate rotator 25 rotates the substrate W together with the substrate holder 20. Hereinafter, the surface Wa of the substrate W is sometimes referred to as the substrate surface Wa.

While the substrate W is rotating, steps S102 to S107 are performed on the substrate surface Wa. First, the nozzle 41 supplies IPA to the substrate surface Wa (step S102). The nozzle 41 supplies the IPA to the center of the substrate surface Wa. The IPA flows radially outward on the substrate surface Wa by centrifugal force, forming a liquid film over the entire substrate surface Wa.

Next, the nozzle 41 supplies the etching solution to the substrate surface Wa (step S103). The etching solution contains HF and IPA, with a HF aqueous solution diluted by IPA. The nozzle 41 supplies the etching solution to the center of the substrate surface Wa. The etching solution flows radially outward on the substrate surface Wa by centrifugal force while replacing the IPA remaining on the substrate W, forming a liquid film over the entire substrate surface Wa.

Next, the nozzle 41 supplies IPA to the substrate surface Wa (step S104). The nozzle 41 supplies the IPA to the center of the substrate surface Wa. The IPA flows radially outward on the substrate surface Wa by centrifugal force while replacing the etching solution remaining on the substrate W, forming a liquid film over the entire substrate surface Wa.

Next, the nozzle 41 supplies a mixed solution of IPA and DIW to the substrate surface Wa (step S105). The nozzle 41 supplies the mixed solution of IPA and DIW to the center of the substrate surface Wa. The mixed solution of IPA and DIW flows radially outward on the substrate surface Wa by centrifugal force while replacing the IPA remaining on the substrate W, forming a liquid film over the entire substrate surface Wa. In step S104, with the passage of time, the content of IPA may be reduced stepwise or continuously, and the content of DIW may be increased stepwise or continuously.

Next, the nozzle 41 supplies DIW to the substrate surface Wa (step S106). The nozzle 41 supplies pure DIW to the center of the substrate surface Wa. The DIW flows radially outward on the substrate surface Wa by centrifugal force while replacing the IPA remaining on the substrate W, forming a liquid film over the entire substrate surface Wa. By supplying the pure DIW, fluorine ions originated from the etching solution may be removed.

After completing the supply of all types of the processing solutions, the substrate rotator 25 rotates the substrate W together with the substrate holder 20, thereby spin-drying the substrate W (step S107). When spin-drying the substrate W, IPA may be supplied again after the supply of the DIW, forming an IPA liquid film on the substrate surface Wa. Since IPA has a lower surface tension than DIW, it may prevent the collapse of an uneven pattern. The drying method for the substrate W is not limited to spin drying, and may be, for example, hydrophobic drying using a silanizing agent or supercritical drying.

According to the present embodiment, an organic solvent that is substantially free of water is supplied to the substrate surface Wa before and/or after the supply of the etching solution (step S103) (both in the case of FIG. 3). When it is stated herein that the organic solvent is substantially free of water, it means that the content of water is between 0.0% by mass and 3.0% by mass.

If the organic solvent is supplied to the substrate surface Wa in step S102 before step S103, it is easier for the etching solution to wet the substrate surface Wa in step S103. The use of the organic solvent that is substantially free of water is intended to prevent the etching of the silicon nitride film W4 caused by water remaining on the substrate W in step S103.

If the organic solvent is supplied to the substrate surface Wa in step S104 after step S103, the etching solution remaining on the substrate W may be removed. Herein, the use of the organic solvent that is substantially free of water is intended to prevent the etching of the silicon nitride film W4 caused by HF and water remaining on the substrate W in step S104.

Further, according to the present embodiment, after the supply of the etching solution (step S103), the following steps are performed in this order: supplying an organic solvent that is substantially free of water to the substrate surface Wa (step S104), supplying a mixed solution of an organic solvent and water to the substrate surface Wa (step S105), and supplying pure water to the substrate surface Wa (step S106). This allows a composition of a liquid film to be gradually changed from an organic solvent to pure water.

Although the embodiments of the substrate processing method and the substrate processing apparatus according to the present disclosure have been described above, the present disclosure is not limited to the above embodiments. Various changes, modifications, substitutions, additions, deletions, and combinations are possible within the scope set forth in the claims. These also naturally belong to the technical scope of the present disclosure.

This application claims priority based on Japanese Patent Application No. 2022-135695 filed on Aug. 29, 2022 in the Japan Patent Office, the entirety of which is incorporated herein by reference.

### EXPLANATION OF REFERENCE NUMERALS

1: substrate processing apparatus, 20: substrate holder, 25: substrate rotator, 31: supplier, 90: controller, W: substrate, W2: titanium nitride film, W5: zirconium oxide film, Wa: surface

1. A substrate processing method comprising:
preparing a substrate including a surface on which a titanium nitride film and a zirconium oxide film are exposed; and
selectively etching the zirconium oxide film from among the titanium nitride film and the zirconium oxide film by supplying an etching solution, which contains hydrogen fluoride and an organic solvent, to the surface of the substrate.

2. The substrate processing method of claim 1, wherein a silicon nitride film is further exposed on the surface of the substrate, and
wherein the zirconium oxide film is selectively etched from among the titanium nitride film, the silicon nitride film, and the zirconium oxide film by supplying the etching solution to the surface of the substrate.

3. The substrate processing method of claim 2, wherein a conductive film, the silicon nitride film, and the zirconium oxide film are stacked in this order on the titanium nitride film, and
wherein an opening is formed to penetrate the zirconium oxide film, the silicon nitride film, the conductive film, and the titanium nitride film.

4. The substrate processing method of claim 3, wherein the conductive film includes a Ru film, a W film, or a Mo film.

5. The substrate processing method of claim 4, wherein the etching solution contains 0.7% by mass to 6.5% by mass of hydrogen fluoride, 87.0% by mass to 98.6% by mass of the organic solvent, and 0.7% by mass to 6.5% by mass of water.

6. The substrate processing method of claim 4, wherein the zirconium oxide film contains an organic matter.

7. The substrate processing method of claim 4, wherein the etching solution contains, as the organic solvent, isopropyl alcohol (IPA), ethylene glycol, acetic acid, ethanol, or methanol.

8. The substrate processing method of claim 4, wherein a temperature of the substrate when supplying the etching solution is equal to or less than 50 degrees C.

9. The substrate processing method of claim 4, comprising:
supplying an organic solvent that is substantially free of water to the surface of the substrate at least one of before the supplying the etching solution or after the supplying the etching solution.

10. The substrate processing method of claim 4, comprising, after the supplying the etching solution:
supplying an organic solvent that is substantially free of water to the surface of the substrate;
supplying a mixed solution of an organic solvent and water to the surface of the substrate; and
supplying pure water to the surface of the substrate, in this order.

11. The substrate processing method of claim 1, wherein the etching solution contains 0.7% by mass to 6.5% by mass of hydrogen fluoride, 87.0% by mass to 98.6% by mass of the organic solvent, and 0.7% by mass to 6.5% by mass of water.

12. The substrate processing method of claim 1, wherein the zirconium oxide film contains an organic matter.

13. The substrate processing method of claim 1, wherein the etching solution contains, as the organic solvent, isopropyl alcohol (IPA), ethylene glycol, acetic acid, ethanol, or methanol.

14. The substrate processing method of claim 1, wherein a temperature of the substrate when supplying the etching solution is equal to or less than 50 degrees C.

15. The substrate processing method of claim 1, comprising:
supplying an organic solvent that is substantially free of water to the surface of the substrate at least one of before the supplying the etching solution or after the supplying the etching solution.

16. The substrate processing method of claim 1, comprising, after the supplying the etching solution:
supplying an organic solvent that is substantially free of water to the surface of the substrate;
supplying a mixed solution of an organic solvent and water to the surface of the substrate; and
supplying pure water to the surface of the substrate, in this order.

17. A substrate processing apparatus comprising:
a substrate holder configured to hold a substrate including a surface on which a titanium nitride film and a zirconium oxide film are exposed; and
a supplier configured to supply an etching solution, which contains hydrogen fluoride and an organic solvent, to the surface of the substrate held by the substrate holder, so as to selectively etch the zirconium oxide film from among the titanium nitride film and the zirconium oxide film.
